(19) United States
(12) Patent Application Publication
(10) Pub. No.: US 2004/0250767 A1
(43) Pub. Date: Dec. 16, 2004

(54) Method and apparatus for coating a substrate using combustion chemical vapor deposition

(75) Inventors: Marc Langlois, Atlanta, GA (US); Anthony A. Cox, Norcross, GA (US)

Correspondence Address: EDWARDS & ANGELL, LLP, P.O. Box 55874, Boston, MA, 02205, US

(73) Assignee: Rohm and Haas Electronic Materials, L.L.C., Marlborough, MA

(21) Appl. No.: 10/828,952

(22) Filed: Apr. 21, 2004

Related U.S. Application Data
(60) Provisional application No. 60/464,282, filed on Apr. 21, 2003.

(51) Int. Cl. C23C 16/00

(52) U.S. Cl. 118/715; 427/248.1

(57) ABSTRACT

A method and apparatus for coating a surface of a substrate using combustion chemical vapor deposition is disclosed. A chemical vapor deposition stream, composed of a coating precursor and a combustible medium, is directed toward a substrate and combusted to provide a reacted coating precursor in a gaseous plume. The plume is modified by exposing it to a shield prior to the plume contacting the surface of the substrate and depositing a coating thereon. The shield serves to control the coating thickness and material characteristics of the deposited material.

### BACKGROUND

This invention relates to a method and apparatus for coating a substrate using combustion chemical vapor deposition, and more particularly, to a method and apparatus for controlling the deposition of a coating on a substrate that may be used for the manufacture of electronic components.

Chemical Vapor Deposition (CVD) is a well known materials synthesis process for depositing coatings on a surface by providing a gaseous reactant material that reacts at a substrate surface to produce a solid deposit or coating thereon. Combustion chemical vapor deposition (CCVD) is a well known extension of the CVD process where the reactants are provided in a combustible liquid mixture and sprayed into a reaction zone from a nozzle using a propellant. The sprayed mixture may be ignited to produce a flame, or may be introduced into a flame, thereby vaporizing the reactants. A substrate disposed near the end of the flame provides a surface on which the vaporized reactants may condense, thereby producing a deposited film on the substrate surface. U.S. Pat. Nos. 5,652,021 and 6,368,665 describe both the CVD and CCVD processes and provide further references thereto.

Another material deposition technique as described in U.S. Pat. No. 5,156,727 is cathode sputtering. Here, ions are accelerated toward a cathode to dislodge, or sputter off, atoms of the target coating at a surface of the cathode, which are then reacted with a reactive gas to form a thin film of the desired coating material at a surface of a substrate. To account for variations in the loss of field uniformity at the extreme ends of the cathode, adjustable masks are used to intercept a portion of the sputtered material thereby preventing the material from reaching and depositing on the substrate. Here, an increase in masking results in a reduction in material deposition.

Deposition masking is also described in U.S. Pat. No. 6,063,436, which discloses an empirical process for successively trimming a plurality of shadow masks for use in an ion beam material deposition process. Here, each shadow mask is specifically tuned to a particular spatial distribution of coating material, referred to as a “plume”, to produce a uniform deposition coating of that particular material on a substrate surface. For each layer of material, a unique mask is provided.

While suitable for a wide variety of purposes, there nonetheless remains a need in the art for a CCVD process that provides for greater control of the deposition process, and greater control over the material characteristics of the resulting product.

### STATEMENT OF THE INVENTION

In a first aspect, there is provided a method of coating a surface of a substrate comprising providing and directing a chemical vapor deposition stream, comprising a coating precursor and a combustible medium, toward the substrate and combusting the stream to provide a reacted coating precursor in a gaseous plume, modifying the plume by causing the plume to pass through an orifice of a shield prior to the plume contacting the surface of the substrate and by controlling the size of the orifice through which the plume passes, and causing the plume to contact a portion of the surface to deposit a coating thereon. Wherein, the coating thickness is at least partially controlled by the temperature of the substrate exposed to the plume and the degree of condensation occurring at the surface, the temperature of the substrate is at least partially controlled by the size of the orifice, and the coating thickness increases in response to an increase in turbulence reducing the boundary layer at the substrate surface.

In another aspect, there is provided an apparatus for coating a surface of a substrate comprising a source of chemical vapor deposition material, a vapor deposition shield disposed between the source and the substrate, the shield having an adjustable orifice for passage of the plume and for controlling the thickness of the coating applied to the surface of the substrate, and means for adjusting the orifice such that the coating thickness at the surface changes in response to a change in orifice size.

In another aspect, there is provided an article comprising a conductive substrate having a surface with a resistive coating thereon produced by the method described above.

As herein disclosed, use of a shield in a CCVD process has the surprising effect of increasing the material deposition and reducing the deposition impurities by selectively intercepting heavy, line of sight material, and decreasing the boundary layer at the plume-substrate interface and thereby increasing movement of reactive material to the substrate. This is especially the case when used in the method and apparatus herein disclosed and contemplated.

### DETAILED DESCRIPTION

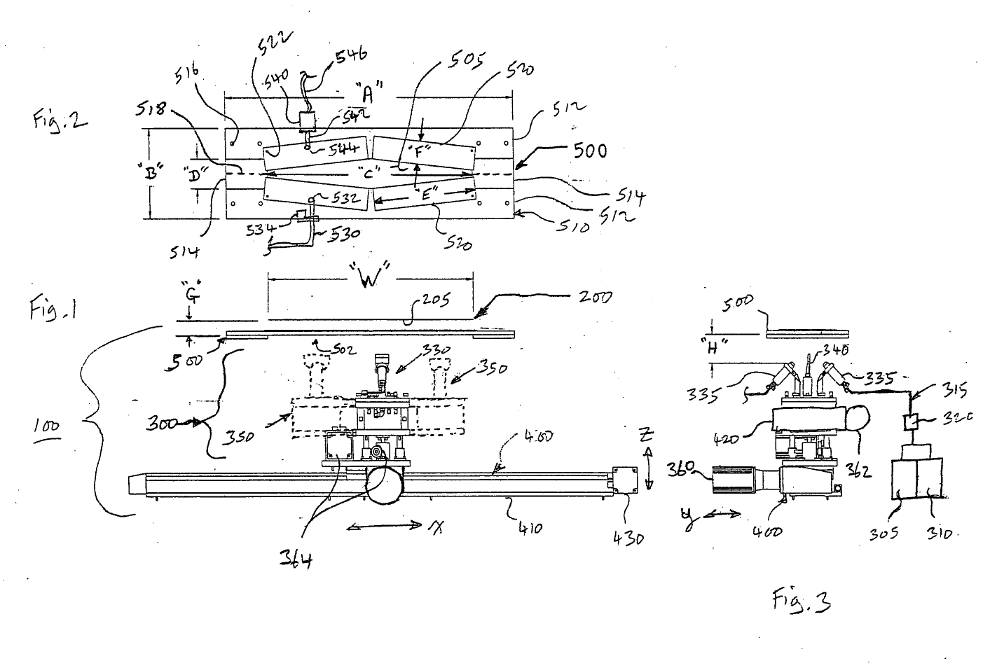

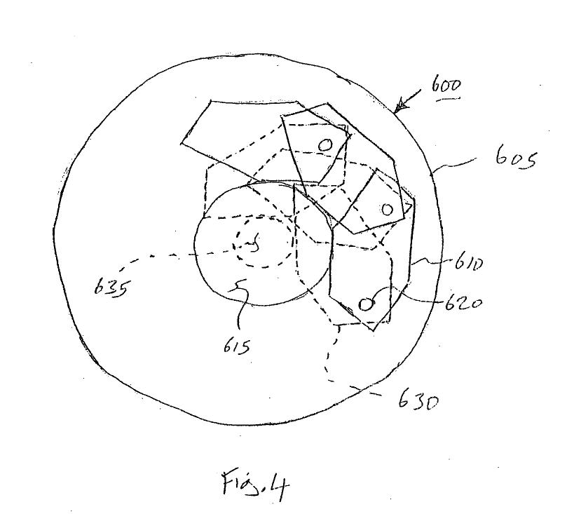

As disclosed herein, FIGS. 1-3 depict orthogonal views of an exemplary apparatus 100 for coating a surface 205 of a substrate 200, which may be copper foil, for example. In an embodiment, apparatus 100 includes a source 300 of chemical vapor deposition material (CVDM), a support structure 400 for supporting portions of source 300, and a vapor deposition shield (shield) 500 disposed between source 300 and substrate 200. Source 300 includes a coating precursor material stored at a storage vessel 305, a combustible medium stored at a storage vessel 310, a conduit system 315 having in-line devices 320, such as flow meters, valves, pumps, and filters, for example, and a delivery system 330 for delivering combusted CVDM to surface 205. While conduit system 315 is depicted in FIG. 3 in a one-line diagram form, it will be appreciated that each storage vessel 305, 310 may have its own conduit system 315 with in-line devices 320, and that source 300 may have more than one each of storage vessels 305, 310, each with their own conduit system 315 with in-line devices 320. An exemplary coating precursor material for providing a resistive coating is a liquid composition of one or more resistive materials in one or more solvents. Suitable precursors are disclosed in U.S. Pat. No. 6,193,911 (Hunt et al.). Exemplary resistive materials include silicon, platinum, iridium and ruthenium.

In an embodiment, the resistive coating is platinum-based, i.e. the major component of the coating is platinum. Exemplary resistive materials contain from 10 to 70 mole percent iridium, ruthenium or mixtures thereof, and typically from 2 mole percent to 50 mole percent, calculated relative to platinum being 100 percent. If ruthenium is used alone (without iridium), it may used at between 2 and 10 mole percent calculated relative to platinum being 100 percent. If iridium is used alone (without ruthenium), it may be used at between 20 and 70 mole percent calculated relative to platinum being 100 percent. In the resistive coatings deposited using the present apparatus, the iridium, ruthenium or mixtures thereof exist in both elemental form and in oxide form. As an example, the iridium, ruthenium or mixtures thereof are from 50 to 90 mole percent elemental metal and from 10 to 50 mole percent oxide(s) of the iridium, ruthenium or mixtures thereof.

In depositing the resistive coatings, a precursor solution is typically prepared containing the precursors for both platinum and the precursor(s) for silicon, iridium, ruthenium or mixtures thereof. Suitable precursors for platinum include, but are not limited to, platinum acetylacetonate (“PtAcAc”) and diphenyl-(1,5-cyclooctadiene) platinum (II) (“PtCOD”). Suitable precursors for iridium and ruthenium include, but are not limited to, tris (norbomadiene) iridium (III) acetyl acetonate (“IrNBD”), and bis (ethylcyclopentadienyl) ruthenium (II). The precursors are dissolved in one or more solvents, such as toluene or toluene/propane to a concentration (total of platinum, iridium, and/or ruthenium precursors) of from 0.15 wt % to 1.5 wt %. This solution is then typically passed through an atomizer to disperse the precursor solution into a fine aerosol and the aerosol is ignited in the presence of a combustible material to produce the platinum and silicon, iridium, ruthenium or mixture thereof zero valence metals(s) and oxide(s). An exemplary combustible material is methane, propane and oxygen in separate storage vessels. When combusted, the resulting flame of CVDM serves to provide a reacted coating precursor in a gaseous plume, which is herein referred to as a plume. Conduit system 315 serves to deliver the contents of storage vessels 305, 310 to delivery system 330.

In an embodiment, delivery system 330 includes a pair of combustion nozzles 335 and an air nozzle 340. An ignition system (not shown) may also be arranged at delivery system 330. While FIG. 3 depicts only one combustion nozzle 335 in fluid communication with storage vessels 305, 310, it will be appreciated that this is for clarity only and that all functional combustion nozzles 335 are similarly connected. Combustion nozzle 335 may be any type of nozzle suitable for providing a combustion chemical vapor deposition (CCVD) material to substrate 200. Some examples of suitable nozzles used for CCVD are described in U.S. Pat. Nos. 5,652,021, 6,368,665, and 6,500,350. Single or multiple combustion nozzles 335 may be used, with or without air nozzle 340, thereby providing for the choice of a point source plume, a narrow linear source plume, or a broad linear source plume. A plurality of pairs of combustion nozzles 335 are depicted in phantom 350 in FIG. 1. A single pair of combustion nozzles 335 with air nozzle 340 would provide a narrow linear source plume, while a plurality of pairs of combustion nozzles 350 each with air nozzles 340 would provide a broad linear source plume. Source 300 is supported by support structure 400, which may include an x-rail 410, a y-rail 420, a z-mount 430, or any combination thereof, for providing for motion of source 300 in the x, y, and z directions. Z-mount 430 may be mounted on a z-rail (not shown) to provide for such motion. The motion of source 300 is by suitable means, such as an x-axis servo motor and drive 360, a y-axis servo motor and drive 362, and a z-axis servo motor and drive 364, for example.

FIG. 1 depicts substrate 200 having dimension “W” oriented in the x-direction, which represents the width of a rectangular sheet of substrate material, the width of a continuous feed of substrate material, or the width of a web-based arrangement of substrate material. In an exemplary arrangement, dimension “W” is 76.2 centimeters (cm) (30-inches (in)). Substrate 200 is supported relative to source 300 by suitable means (not shown). The x, y, z motion of source 300 provides for relative motion between source 300 and substrate 200, thereby enabling CCVD coverage across the entire undersurface 205 of substrate 200. Alternatively, source 300 may be stationary and substrate 200 may be movable in the x, y and z directions.

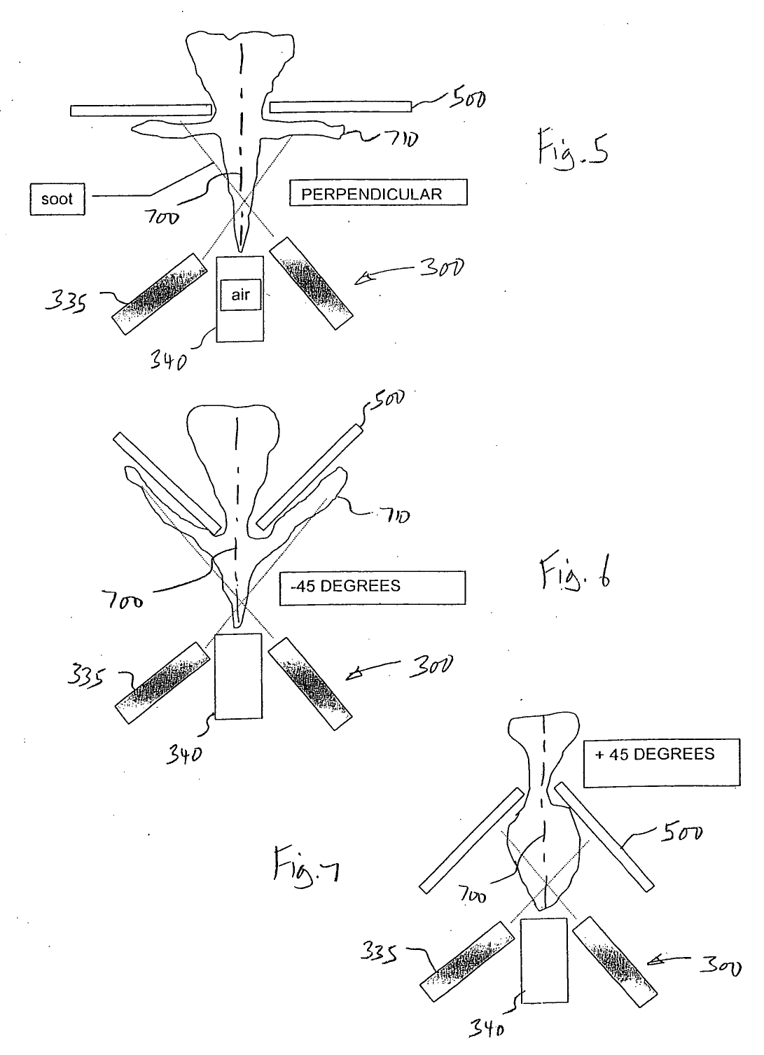

Disposed between source 300 and substrate 200 is shield 500 having an adjustable orifice 505 that provides a means for controlling the plume, the soot extraction from the plume, and the thickness of the coating applied to surface 205 by the plume. With regard to soot extraction, the combustion of solvent-based precursors via a CCVD process is not complete and results in unburned residue, herein referred to as “soot”, which may be collected on the underside of shield 500, as will be discussed in more detail below in reference to FIGS. 5-7. With regard to the coating thickness at surface 205, coating deposition via a CCVD process occurs by way of condensation of the vaporized precursor on the heated substrate surface. Accordingly, it has been found that an increase in coating thickness may be achieved by increasing the amount of turbulence in the plume reaching surface 205, which decreases the boundary layer at surface 205 and thereby provides for a greater degree of precursor condensation and coating deposition. Thus, an increase in shielding results in an increase in coating thickness, which is counter intuitive to the process described in U.S. Pat. No. 5,156,727, where an increase in masking results in a decrease in coating deposition. The significance of being able to control the coating thickness will be discussed in more detail below.

In an embodiment, orifice 505 is bounded by a frame 510 and a plurality of movable plates 520. Frame 510 includes side members 512 and end members 514, connected by suitable hardware depicted at 516. In an exemplary arrangement, the outside dimensions of frame 510 are 106.7 cm (42-inches) in the x-direction (dimension “A”) and 30.5 cm (12-inches) in the y-direction (dimension “B”). Movable plates 520 are pivotally connected at one corner to frame 510 by suitable hardware depicted at 522. The pivotal arrangement of movable plates 520 provides a means for adjusting the size and shape of orifice 505, which in an exemplary arrangement, and in the absence of movable plates 520, has dimensions of 76.2 cm (30-inches) in the x-direction (dimension “C”) and 10.2 cm (4-inches) in the y-direction (dimension “D”). Exemplary movable plates 520 have dimensions of 38.1 cm (15-inches) by 7.6 cm (3-inches) (dimensions “E” and “F”, respectively). A suitable material for frame 510 and movable plates 520 is 3-millimeter (mm) thick (10-gauge) stainless steel.

In an embodiment, the adjustment of movable plates 520 may be done manually by loosening hardware 522, adjusting plates 520, and re-tightening hardware 522. In an alternative embodiment, movable plates 520 may be adjusted by an operator external to apparatus 100 by use of a sheathed push-pull cable 530 having an inner cable attached to plate 520 at 532, and an outer sheath supported by frame 510 at 534. In a further alternative embodiment, movable plates 520 may be adjusted by a control system (not shown) external to apparatus 100, that uses a linear motor 540 having an extension arm 542 attached to movable plate at 544 and control wires 546 in signal communication with the control system. While FIG. 2 depicts only one push-pull cable 530 arrangement, and only one linear motor 540 arrangement, it will be appreciated that each movable plate 520 may have its own drive system for individual control. Alternatively, it is contemplated that one drive system may be employed that operates all movable plates 520 in unison. Furthermore, it is also contemplated that a variety of sensors, such as temperature, humidity, mass flow, and optical recognition, for example, may be incorporated in apparatus 100 to provide feedback signals for automatically controlling orifice 505 via the control system depending on the manufacturing variations experienced during a production run or the material characteristics desired.

As depicted in FIG. 2, movable plates 520 are arranged such that orifice 505 is larger at the center and smaller at each end, with the center of orifice 505 being proximate the center of substrate 200, and each end of orifice 505 being proximate a respective edge of substrate 200 having width “W”. Thus, as a single pair of combustion nozzles 335 travel in the x-direction from the center to the edge of substrate 200, the plume passing through orifice 505 experiences a decreased available opening and an increased amount of shield, the significance of which will be discussed further below.

An alternative arrangement for decreasing the size of orifice 505 as the combustion nozzles 335 travel from the center to the edge of substrate 200, is to provide a shield 600, best seen by now referring to FIG. 4, having a near-circular orifice 615 with an adjustable diameter, similar to what may be found in a photography camera having an adjustable aperture, fixing the shield in relation to the plume and source 300, and adjusting the orifice diameter as source 300 travels across the width “W” of substrate 200. As depicted in FIG. 4, an embodiment of shield 600 includes eight pivotally arranged plates 610 (only three plates shown for clarity) that pivot in unison about pivot axis 620. In a first orientation, plates 610, shown in solid line fashion, provide a near-circular orifice 615 having a first diameter, and in a second orientation, plates 630, shown in dashed line fashion, provide a near-circular orifice 635 having a second diameter, where the first diameter is larger than the second diameter. To accomplish a similar result as discussed above in relation to shield 500 of FIG. 2, shield 600 would be adjusted to have the first diameter of orifice 615 when source 300 was at the center of substrate 200, and adjusted to have the second diameter of orifice 635 when source 300 was at the edge of substrate 200. A cam action known in the art may be used to pivot plates 610 in unison. As shield 600 traverses substrate 200 with source 300, a control system, similar to that discussed above, may be used to adjust aperture 615, 635 on command.

Reference is now made to FIGS. 5-7. In FIG. 5, shield 500 is depicted having a perpendicular orientation relative to the centerline of plume 700. In FIG. 6, shield 500 is depicted having a −45 degree orientation relative to the centerline of plume 700. In FIG. 7, shield 500 is depicted having a +45 degree orientation relative to the centerline of plume 700. To generate the angled shields 500 depicted in FIGS. 6 and 7, shield 500 of FIG. 2 is bent at dashed line 518 (see FIG. 2). The contemplated effect on the plume as a result of the angling of shield 500 is also illustrated in each of FIGS. 5-7. It has been found that a change in the angle of shield 500 results in a change in both the amount of contaminants reaching substrate 200, with its attendant change in the amount of soot collected on the underside of shield 500, and also a change in the amount of materials deposited onto the substrate. Thus, by changing the angle of shield 500, additional control with respect to the composition and characteristic of the plume and with respect to the characteristics and composition of the coating on substrate 200, may be achieved. The plume wings 710 depicted in FIGS. 5 and 6 represent the effectiveness of shield 500 to collect the unburned soot present in the plume. As depicted, a −45 degree angle of shield 500 results in a noticeable amount more soot collection than does a perpendicular orientation, and a +45 degree orientation results in substantially less soot collection. Since the degree of soot present in the plume that reaches substrate 200 has an effect on the characteristics, and particularly the electrical characteristics, of the coating deposited on surface 205, it follows that the angular orientations of shield 500 as depicted in FIGS. 5 and 6 would result in less impurities in the coating than would the angular orientation as depicted in FIG. 7. Further, it will be noted that, depending upon the opening width, a perpendicular or a −45 degree orientation results in substantially less heat and deposition material reaching the substrate.

The operation of apparatus 100, and particularly the operation of apparatus 100 with shield 500 will now be further described. Apparatus 100 is typically operated under a hood (not shown) that may be evacuated through a filter, thereby providing a means for controlling the atmosphere that contributes atmospheric gases and other impurities to the plume, and for controlling the amount of combustion byproducts delivered back to the atmosphere. The delivery and combustion of the combustible precursor at combustion nozzles 335 is well known and discussed in detail in the references cited above, however, use of shield 500 in a CCVD process is not known and will herein be further discussed. In the single nozzle pair embodiment of FIG. 1, source 300 is rastered in the x and y directions to provide complete deposition coverage of surface 205. Since surface 205 is exposed to the heat of the plume as well as the vaporized precursor within the plume, the temperature at surface 205 will vary as a function of the source energy, source placement, and source raster rate. As source 300, in the absence of shield 500, traverses substrate 200 from a center region to an edge region, an increase in temperature at the edge of substrate 200 will result due to the reduced thermal mass of substrate 200 in the vicinity of the edge, and moreover, from the reduced cool down time seen before the commencement of the next pass of the torch. This is especially true at fast raster rates. In the absence of shield 500, this increase in substrate temperature at the edge has the effect of changing the amount of chemical vapor deposition at the edge since the degree of condensation changes as a function of the surface temperature. The end result, without shield 500, is a substrate 200 having a surface 205 with a coating having a first thickness at the center region and a second thickness at the edge region. To counter this variation in coating thickness, shield 500 is introduced to control the amount of heating at surface 205, thereby effecting the resulting degree of vapor condensation and coating deposition. As depicted in FIGS. 1 and 2, as source 300 traverses substrate 200 from a center region to an edge region in an x-direction, the size of orifice 505 of shield 500 decreases from a large y-direction opening to a small y-direction opening, where an exemplary large y-direction opening is 10.2 cm (4-inches) and an exemplary small y-direction opening is 2.5 cm (1-inch). The reduced size of orifice 505 at the edge region of substrate 200 serves to reduce the amount of heating of surface 205 by the plume, thereby resulting in a more uniform amount of vaporized precursor being condensed out on the more uniform temperature substrate surface. By controlling the size of orifice 505 as disclosed, a more uniform coating thickness on surface 205 results. Also, by controlling the orifice size, faster raster rates and reduced raster travel may be used.

Another result of using shield 500 is the collection of unburned soot on the underside surfaces 502 of shield 500. As previously disclosed in above referenced patents, the velocity of the liquid precursor leaving the torch is quite high. Due to the incomplete combustion seen in this process, as the unburned or un-reacted material continue on their path through the flame, they are of sufficient mass to not be deflected by the air stream, and continue to travel in a relatively straight path and impinge on the shield. This would be adjustable, and analogous to the well known technique of mass separation used in analytical instruments, such as mass spectrometers. As further depicted in FIGS. 5-7 and discussed above, the angle of shield 500 may also be adjusted to further enhance the degree of soot collection. Also, and with reference to FIG. 4, the degree of soot collection may be further enhanced by using a circular orifice 615 in conjunction with a plume having a circular cross section, which has the effect of intercepting the entire range of angles seen by the heavy un-reacted material, thereby permitting only the center higher temperature portion of the plume to reach surface 205. A process that reduces soot results in less impurities in the coating at surface 205 and increases deposition efficiency due to the removal of unwanted material.

A further result of using shield 500 is the control of the amount of atmosphere that is entrained by the plume, thereby controlling the plume shape and composition for improved deposition efficiency.

Yet a further result of using shield 500 is the control of the coating thickness on surface 205 to achieve a desired surface characteristic (such as resistivity or capacitance for example), to compensate for surface imperfections (such as curvature for example), or to adjust for changes in manufacturing processes (such as ambient or substrate temperature for example).

Another result of using shield 500 is the ability to raster, or move, the shield and not the deposition source, thus leading to “smearing” of the edges of individual CCVD unit plumes as they interact with the substrate. In an embodiment of apparatus 100, the location, shape or angle between the shield and deposition plume may be controlled, thereby intentionally enabling the production of non-uniform coatings on flat or non-flat substrates.

Embodiments of the invention are further illustrated by the following examples.

As discussed above, an exemplary CCVD precursor mixture includes one or more compounds containing silicone, platinum, iridium, and toluene as a solvent, which is delivered to combustion nozzles 335 by conduit system 315, ignited into a plume, and directed toward surface 205 of substrate 200. Two combustion nozzles 335 pointing toward each other are mounted on delivery system 330 at an angle of 40-degrees from a horizontal and arranged such that the centerline of the ignited plumes intersect at a point two-thirds of the way up the plume. An air nozzle 340 (also referred to as a linear redirect air knife) is arranged tinder the plume intersect point to redirect the deposition cloud (generally referred to as the plume) in a vertical direction toward substrate 200. Shield 500 having the structure and dimensions discussed above is disposed between source 300 and substrate 200 such that surface 205 is between 2.5 and 3.8 cm (1 and 1.5 inches) above shield 500 (dimension “G”), and shield 500 is between 9.5 and 10.2 cm (3.75 and 4 inches) above the exits of combustion nozzles 335 (or above the base of the plumes) (dimension “H”). With a pair of nozzles 335, source 300 repeatedly traverses substrate 200 in the x-direction from one edge to the other to provide a coating thereon. With a linear array of nozzles 350, source 300 may be stationary with respect to the x-direction. Either source 300 or substrate 200 may travel in a y-direction for complete surface coverage. Source 300 or substrate 200 may also travel in a z-direction for further control of the deposition process.

In another embodiment, shield 500 of FIG. 2 may be replaced with shield 600 of FIG. 4, which has a frame 605 with an outside diameter of 30.5 cm (12-inches), and a plurality of adjustable plates 610 capable of providing an orifice 615, 635 that varies from 10.2 cm (4-inches) to 2.5 cm (1-inch) in diameter. Shield 600 is mounted to source 300 by suitable means such that shield 600 travels with source 300 as surface 205 is coated. As discussed above, control means, not shown, external to apparatus 100 may be used to dynamically change orifice 615, 635 during operation.

The apparatus and process disclosed herein may be used to apply resistive coatings to conductive sheets for use as resistors or non-conductive coatings for capacitors, for example, in printed circuit boards. However, it is contemplated that the production of other electronic components may also benefit from embodiments of the disclosed invention. For example, the present apparatus may be useful in the deposition of dielectric materials for use in capacitors.

Embodiments of the invention are further exemplified by the following.

A method of coating a surface of a substrate, including: providing and directing a chemical vapor deposition stream comprising a coating precursor and a combustible medium toward the substrate and combusting the stream to provide a reacted coating precursor in a gaseous plume; modifying the plume by causing the plume to pass through an orifice of a shield prior to the plume contacting the surface of the substrate and by controlling the size of the orifice through which the plume passes; and, causing the plume to contact a portion of the surface to deposit a coating thereon. Wherein: the coating thickness is at least partially controlled by the temperature of the substrate exposed to the plume and the degree of condensation occurring at the surface; the temperature of the substrate is at least partially controlled by the size of the orifice; and, the coating thickness changes in response to a change in orifice size that modifies the surface temperature and thus the degree of condensation of the coating at the surface.

The method described above including a method of controlling the size of the orifice such that the size of the orifice at an edge-portion of the surface is smaller than the size of the orifice at a non-edge-portion of the surface.

An apparatus for coating a surface of a substrate, having: a source of chemical vapor deposition material, the material comprising a coating precursor and a combustible medium that is capable of combusting to provide a reacted coating precursor in a gaseous plume; a vapor deposition shield disposed between the source and the substrate, the shield having an adjustable orifice for passage of the plume and for controlling the thickness of the coating applied to the surface of the substrate; and means for adjusting the orifice such that the coating thickness at the surface changes in response to a change in orifice size that modifies the surface temperature, deposition material concentration, plume energy and direction, as well as plume flow characteristics, particularly boundary conditions at the plume-substrate interface.

An article comprising a conductive substrate having a surface with a resistive coating thereon produced by the method described above.

What is claimed is:

1. A method of coating a surface of a substrate, comprising:
providing and directing a chemical vapor deposition stream comprising a coating precursor and a combustible medium toward the substrate and combusting the stream to provide a reacted coating precursor in a gaseous plume;
modifying the plume by causing the plume to pass through an orifice of a shield prior to the plume contacting the surface of the substrate and by controlling the size of the orifice through which the plume passes; and
causing the plume to contact a portion of the surface to deposit a coating thereon;
wherein the coating thickness is at least partially controlled by the temperature of the substrate exposed to the plume and the degree of condensation occurring at the surface;
wherein the temperature of the substrate is at least partially controlled by the size of the orifice; and
wherein the coating thickness changes in response to substrate temperature and plume flow characteristics, thereby providing effective control over coating thickness and material characteristics.

2. An apparatus for coating a surface of a substrate, comprising:
a source of chemical vapor deposition material, the material comprising a coating precursor and a combustible medium that is capable of combusting to provide a reacted coating precursor in a gaseous plume;
a vapor deposition shield disposed between the source and the substrate, the shield having an adjustable orifice for passage of the plume and for controlling the thickness of the coating applied to the surface of the substrate; and
means for adjusting the orifice such that the coating thickness at the surface changes in response to a modification of the substrate temperature, plume characteristics and concentrations, thereby effecting the degree of condensation of the coating at the surface.

3. An article comprising a conductive substrate having a surface with a resistive coating thereon produced by the method of claim 1.
